(19) United States
(12) Patent Application Publication
(10) Pub. No.: US 2025/0283216 A1
(43) Pub. Date: Sep. 11, 2025

(54) COATED POLYMERIC ARTICLE AND METHOD OF MAKING SAME

(71) Applicant: TECHNION RESEARCH & DEVELOPMENT FOUNDATION LIMITED, Haifa (IL)

(72) Inventors: Tamar SEGAL-PERETZ, Haifa (IL); Gil MENASHEROV, Haifa (IL)

(21) Appl. No.: 19/074,714

(22) Filed: Mar. 10, 2025

Related U.S. Application Data
(60) Provisional application No. 63/563,376, filed on Mar. 10, 2024.

(51) Int. Cl. C23C 16/40; C08G 63/08; C08K 3/22; C23C 16/455

(52) U.S. Cl. CPC C23C 16/407; C08G 63/08; C08K 3/22; C23C 16/45525; C08G 2230/00; C08K 2201/011

(57) ABSTRACT

A coated polymeric article is disclosed. The article comprises: a polymeric substrate; metal oxide particles embedded in the polymeric substrate; and a metal oxide layer coating the polymeric substrate. The polymeric substrate may be a non-fibrous polymeric substrate.

### CROSS REFERENCE TO RELATED APPLICATIONS

This application claims the benefit of U.S. Patent Application No. 63/563,376, filed Mar. 10, 2024, and titled “COATED POLYMERIC ARTICLE AND METHOD OF MAKING SAME”, which is hereby incorporated by reference in its entirety.

### FIELD OF THE INVENTION

The present invention relates generally to methods of coated polymeric articles. More specifically, the present invention relates to polymeric articles coated with metal oxide layer.

### BACKGROUND OF THE INVENTION

Degradable polymers offer a viable solution to the harmful environmental impact of conventional, non-degradable plastics. However, their widespread adoption is impeded by their lower performance compared to conventional polymers. Degradable polymers are often sensitive to UV radiation which leads to detrimental effects on their structural and mechanical properties. Current solutions involve the inclusion of UV stabilizers or protective additives in the formulation of degradable polymers. Other strategies include utilizing inherently UV-resistant components, applying non-degradable coatings and laminates, and integrating nanoparticles like zinc oxide or titanium dioxide. Exploring the development of organic-inorganic hybrid materials through techniques such as the sol-gel approach, co-polymerization, and chemical vapor deposition (CVD) shows potential in overcoming these limitations.

Incorporation of UV stabilizers or protective additives, while effective in enhancing UV resistance, may introduce concerns related to environmental persistence and recyclability. Synthetic chemicals used as stabilizers may persist in the environment, potentially contributing to pollution. Creating organic-inorganic hybrid materials poses significant challenges across various synthesis methods, particularly in the context of the prevalent liquid solution processing methods like the sol-gel approach. Contemporary challenges include difficulties related to precursor solubility, chemical incompatibility, and surface wetting issues, rendering solution processing impractical in certain systems. It is common for these methods to result in physical mixtures that do not interact synergistically. Additionally, achieving optimal layer uniformity and adhesion in layer-by-layer assembly methods remains a persistent challenge, as does the precise control over the ratio and distribution of organic and inorganic components in co-polymerization processes.

Accordingly, there is a need and an advantage to enhance the UV radiation resistance of polymers (e.g., degradable and nondegradable) using technologies based on atomic layer processes.

### SUMMARY OF THE INVENTION

Some aspects of the invention are directed to an article comprising: a polymeric substrate; metal oxide particles embedded in the polymeric substrate; and a metal oxide layer coating the polymeric substrate. In some embodiments, the polymeric substrate may be a non-fibrous polymeric substrate.

In some embodiments, the metal oxide layer may be at least one of, a continuous layer and a nonstructured layer. In some embodiments, the nonstructured layer may include high density needle-shaped nanostructures.

In some embodiments, the metal oxide particles may be embedded in the polymeric substrate at a depth of at least 10 nm. In some embodiments, the metal oxide layer is characterized by a thickness of between 10 and 500 nm. In some embodiments, the thickness standard deviation is at most 3 nm.

In some embodiments, the polymeric substrate consists of a thermoplastic polymer. In some embodiments, the polymeric substrate is devoid of any UV-related additives. In some embodiments, the UV-related additives are selected from, UV absorbers, UV reflectors, UV blockers, and UV scatters. In some embodiments, the polymeric substrate is a polymeric sheet. In some embodiments, the polymeric sheet is characterized by a thickness between 0.1 μm and 1 mm.

In some embodiments, the metal oxide is characterized by at least one of, a UV-absorbing property and a UV-protective property. In some embodiments, the metal oxide comprises ZnO, TiO2 or both. In some embodiments, the polymeric substrate comprises a biodegradable polymer.

Some aspects of the invention are further directed to a method of making an article according to any one of the embodiments disclosed herein. The method may include passivating a polymeric substrate with a precursor of a metal oxide, to obtain a passivated substrate comprising the metal oxide particles embedded in the polymeric substrate; and depositing a metal oxide layer on the passivated polymeric substrate. In some embodiments, depositing may performed by atomic layer deposition (ALD); and the passivating step may include at least 3 repetitive cycles of sequential infiltration synthesis (SIS).

In some embodiments, the SIS comprises exposing the polymeric substrate with the precursor thereby depositing the precursor into the polymeric substrate; and oxidizing the precursor thereby obtaining the metal oxide. In some embodiments, the exposing is performed at a pressure sufficient for the precursor to penetrate into the polymeric substrate. In some embodiments, the pressure is at least about 2 Torr. In some embodiments, the passivating step comprises between 3 and 50 repetitive cycles of SIS; and the exposing is performed for a time period of at least 100 s.

In some embodiments, the ALD comprises exposing the passivated polymeric substrate with the precursor and oxidizing the precursor thereby obtaining the metal oxide. In some embodiments, the ALD is performed at a pressure between 0.3 and 1 Torr.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is an illustration of an article according to some embodiments of the invention;

FIG. 2 is a flowchart of a method of making an article according to some embodiments of the invention;

FIG. 3 is an illustration of a sequential infiltration synthesis (SIS) according to some embodiments of the invention;

FIG. 4 is an illustration of atomic layer deposition (ALD) processes according to some embodiments of the invention;

FIG. 5 shows graphs of typical pressure profiles for ALD and SIS processes according to some embodiments of the invention;

FIG. 6 shows graphs FTIR spectrum of PLA after 10 SIS cycles+500 ALD cycles at varying time intervals of UV radiation exposure according to some embodiments of the invention;

FIG. 7 shows the percentage of remaining thickness of PLA thin film after 15 min under UV 28˜32 mW/cm²@253.7 nm according to some embodiments of the invention;

FIG. 8 shows the percentage of remaining thickness of PLA thin film after 30 min under UV 28˜32 mW/cm²@253.7 nm the percentage according to some embodiments of the invention;

FIG. 9 shows SEM images of in lens cross section images of PLA thin film A) after 500 cycles of ALD B) after 10 cycles of SIS and C) after 10 SIS cycles followed by 500 ALD cycles according to some embodiments of the invention;

FIG. 10 shows SEM image of ESB cross section images of PLA thin film A) after 500 cycles of ALD B) after 10 cycles of SIS and C) after 10 SIS cycles followed by 500 ALD cycles according to some embodiments of the invention; and

FIG. 11 shows the percentage of the remaining thickness of PMMA, PC, PET and PLA film under UV 28˜32 mW/cm²@253.7 nm, thin films thickness ˜100 nm, according to some embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

Some aspects of the invention are directed to a polymeric based article with high UV resistance. The enhancement of the UV resistance may be achieved by embedding to a polymeric substrate, metal-oxide particles using the SIS process and further coating the polymeric substrate with metal-oxide nano-layer using ALD process.

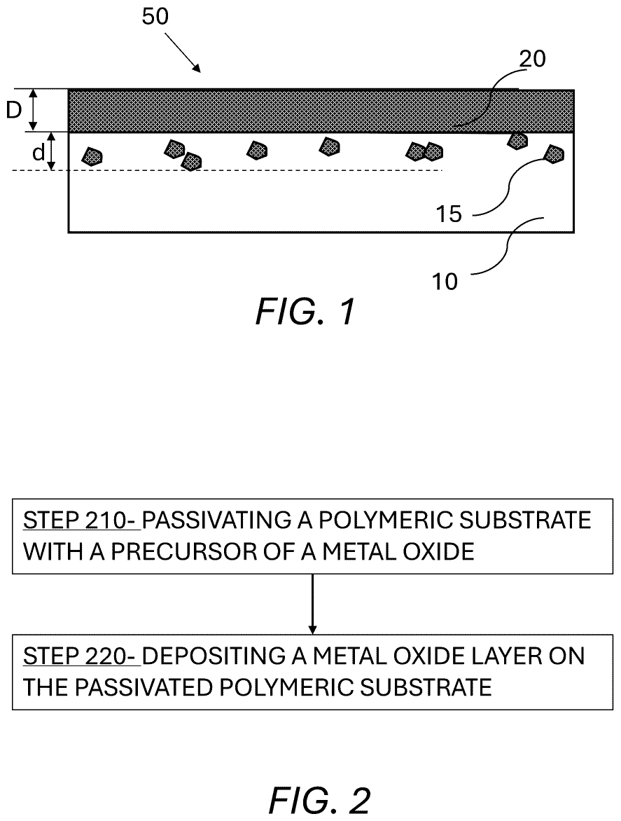

Reference is now made to FIG. 1 which is an illustration of an article according to some embodiments of the invention. An article 100 may include a polymeric substrate 10 and metal oxide particles 15 embedded in polymeric substrate 10. Polymeric substrate 10 may further be coted with metal oxide layer 20.

In some embodiments, polymeric substrate 10 is a non-fibrous polymeric substrate. In some embodiments, the polymeric substrate includes biodegradable polymer and/or non-biodegradable polymer. In some embodiments, polymeric substrate 10 is a thermoplastic polymer. In some embodiments, polymeric substrate 10 may be a polymeric sheet, that may be characterized by a thickness between 0.1 μm and 1 mm, for example, between 0.1 μm to 1 μm, between 1 μm to 10 μm, between 10 to 100 μm, between 100 μm to 500 μm, between 500 μm to 1 mm and any range or value in between.

In some embodiments, polymeric substrate 10 may be devoid of any UV-related additives, for example, the UV-related additives may be selected from, UV absorbers, UV reflectors, UV blockers, and UV scatters.

As used herein a “biodegradable polymer” is defined as a polymer capable of undergoing physical and biological decomposition to result in natural byproducts such as gases (CO₂, O₂, N₂), water, biomass, and inorganic salts. A biodegradable polymer being decomposed in soil will not produce any harmful and toxic products. For purposes of this patent application, biodegradability is considered the property of a material, the chemico-morphological structure of which is modified in a destructive manner (degradation), after interaction with media that contain microorganisms or biologically active combinations of substances generated by microorganisms. The interaction mentioned represents a complex process called “biodegradation”.

Some nonlimiting examples for biodegradable polymers may include biodegradable polyester, or any biodegradable co-polymer thereof. In some embodiments, a biodegradable polyester comprises: Polylactic acid (PLA), a Polyhydroxyalkanoates (PHA's), Poly(butylene adipate-co-terephthalate) (PBAT), Polycaprolactone (PCL), Polybutylene Succinate (PBS), Poly(butylene succinate-co-butylene adipate) (PBSA), Polyglycolide or poly(glycolic acid) (PGA) and, including any combination or any co-polymer thereof.

Some nonlimiting examples for non-biodegradable polymers may include, polyethylene (PE), polyolefins (PO), polyacrylate (PA), polystyrene (PS), polyvinylchloride (PVC) and the like.

In some embodiments, metal oxide particles 15 may be embedded in polymeric substrate 10 during a SIS process. In some embodiments, metal oxide particles 15 include clusters of metal-oxide nanocrystals. In some embodiments, wherein metal oxide particles 15 may be embedded in polymeric substrate 10 at a depth ‘d’ of at least 10 nm, for example, at least 15 nm, at least 20 nm, at least 30 nm, at least 50 nm, at least 70 nm, at least 100 nm, at least 500 nm, and any value or range in between. In some embodiments, the metal oxide is characterized by at least one of, a UV-absorbing property and a UV-protective property. Some nonlimiting examples for metal oxide particles 15 may include ZnO particles, TiO₂ particles and the like.

In some embodiments, metal oxide layer 20 may be applied using ALD processes. Metal oxide layer 20 may be characterized by a thickness ‘D’ of between 10 and 500 nm with a standard deviation is at most 3 nm. For example, ‘D’ may be between 10 and 20 nm, between 20 and 50 nm, between 50 and 100 nm, between 100 and 200 nm, between 200 and 500 nm, and any value of range in between. In some embodiments, metal oxide layer 20 may be at least one of, a continuous layer and a nonstructured layer. For example, the nonstructured layer may include high density needle-shaped nanostructures.

In some embodiments, metal oxide layer 20 may include metal oxide characterized by at least one of, a UV-absorbing property and a UV-protective property. Some nonlimiting examples for metal oxide layers may include ZnO, TiO₂ and the like.

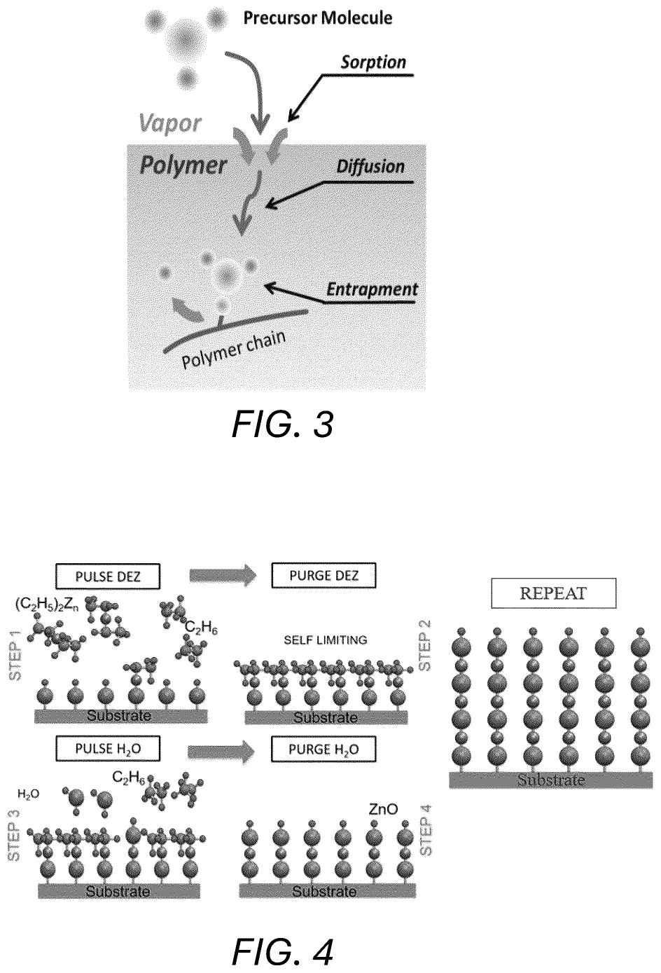

Reference is now made to FIG. 2 which is a flowchart of making an article, such as article 100, according to some embodiments of the invention. In step 210, the method may include passivating a polymeric substrate with a precursor of a metal oxide, to obtain a passivated substrate comprising the metal oxide particles embedded in the polymeric substrate. In some embodiments, passivating comprises at least 3 repetitive cycles of sequential infiltration synthesis (SIS). An illustration of SIS is given in FIG. 3.

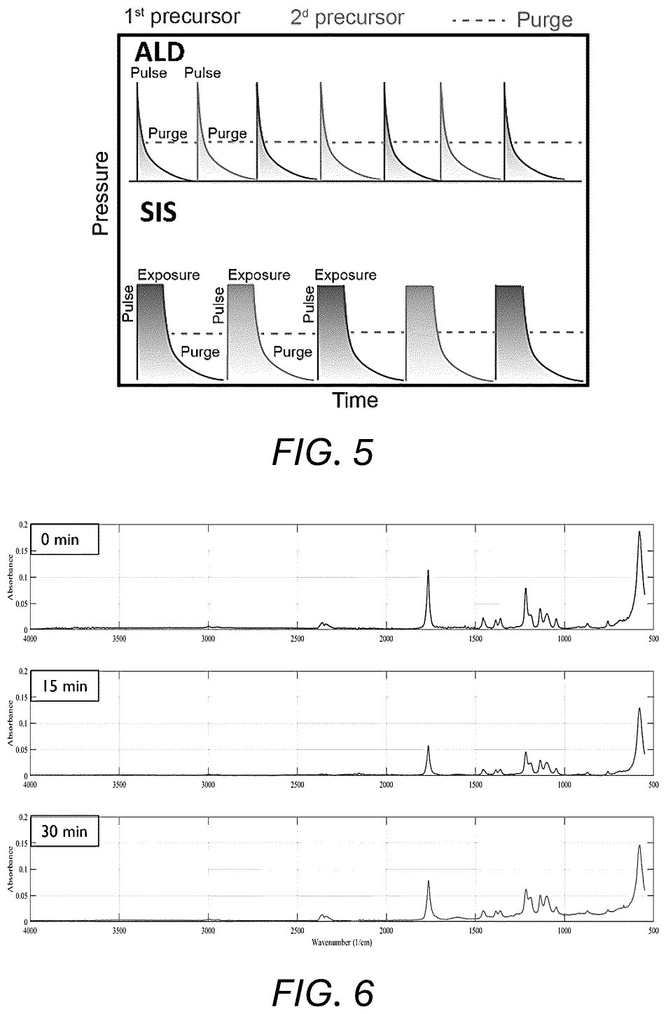

In some embodiments, SIS comprises exposing the polymeric substrate with the precursor thereby depositing the precursor into the polymeric substrate; and oxidizing the precursor thereby obtaining the metal oxide. The exposing may be performed at a pressure sufficient for the precursor to penetrate into the polymeric substrate, for example, at least 2 Torr. A nonlimiting example for the pressure cycle is given in the graphs of FIG. 5.

In some embodiments, the passivating step comprises between 3 and 50 repetitive cycles of SIS; and wherein the exposing is performed for a time period of at least 100 s.

In step 220, the method may include depositing a metal oxide layer on the passivated polymeric substrate, wherein depositing is performed by atomic layer deposition (ALD). An illustration of ALD process is shown in FIG. 4. In some embodiments, the ALD comprises exposing the passivated polymeric substrate with the precursor and oxidizing the precursor thereby obtaining the metal oxide, that may be performed at a pressure between 0.3 and 1 Torr.

### EXAMPLES

Thin films of polylactic acid (PLA) having a thickness of ˜100 nm was fabricated on a silicon wafer using a spin coating technique. Subsequently, the films were subjected to drying at 100° C. for an hour in an inert atmosphere, and their precise thickness was measured using alpha-SE Spectroscopic Ellipsometer. Following this, the models were introduced into a vacuum chamber and sequentially exposed to vapor phase precursors, specifically diethyl zinc (DEZ) and water to form zinc oxide. The process integrated both SIS and ALD methods. Initially, the polymer undergoes SIS, leading to the growth of inorganic materials within the polymer matrix. Subsequently, the process transitions to ALD. The SIS process provides an excellent infrastructure for the ALD process, allowing growth at a uniform rate on the surface of the film.

### Polymer Solution

polylactic acid (PLA) was dissolved (in room temp.) in chloroform to make a 1% by weight solution.

### Film Formation

Thin films of polylactic acid (PLA) with a thickness of ˜100 nm were fabricated on a silicon wafer using a spin coating technique. Spin coating parameters are—speed—3000 RPM, acceleration—3000 and time—60 sec. The films were subjected to drying at 100° C. for an hour in an inert atmosphere, and their precise thickness was measured using alpha-SE Spectroscopic Ellipsometer-Cauchy model.

Following this, the models were introduced into a vacuum chamber and sequentially exposed to vapor phase precursors, specifically diethyl zinc (DEZ) and water to form zinc oxide. During all experiments the parameters of the SIS and ALD processes remained the same.

### Experimental Procedure for UV Protection Layer Formation Through SIS and ALD Cycles

In SIS, metal oxides such as zinc oxide (ZnO) are grown as clusters within the top ˜200 nm of the polymer in the free volume between the polymer chains. SIS processes distinguish themselves from ALD processes by featuring extended exposure times. This extended duration is deliberately designed to allow ample time for precursor molecules to diffuse effectively into the available free volume within the polymer and undergo the necessary reactions.

All SIS processes took place at a temperature of 80 degrees Celsius. To create the UV protection layer, a combination of 10 cycles of SIS followed by 500 cycles of ALD was performed.

The experimental setup commenced by placing the polymer models within a vacuum chamber (reactor) set at 80 degrees Celsius. Nitrogen, with a purity level of 99.999, was introduced at a rate of 20 SCCM for 900 seconds to ensure system stabilization. Following this, the outlet stop valve was closed, nitrogen flow dropped to 5 SCCM. A 0.015-second pulse of DEZ precursor was released, after which both the nitrogen flow and the auxiliary valve (inlet) were closed. The system remained sealed for 1800 seconds with the precursor inside. Subsequently, the inlet and outlet valves were opened, and a 20 SCCM nitrogen flow for 900 seconds facilitated the purging of unreacted precursor. The nitrogen flow decreased to 5 SCCM, the outlet stop valve closed, and a 0.015-second pulse of H₂O precursor was released. Similar to the DEZ pulse, both the nitrogen flow and auxiliary valve were closed for 1800 seconds with the precursor inside the reactor. Subsequently, the inlet and outlet valves were opened, and a 20 SCCM nitrogen flow for 900 seconds facilitated the purging of unreacted precursor. This constituted one SIS cycle, with a total of 10 cycles executed.

Upon completion of the tenth SIS cycle, the continuous ALD process ensued, maintaining a constant nitrogen flow at 20 SCCM. Each ALD cycle involved a 0.015-second pulse of H₂O precursor, followed by a 10-second interval before a 0.015-second pulse of DEZ precursor, and a subsequent 10-second wait before starting a new cycle by releasing another pulse of water. This cycle repeated for a total of 500 cycles, where a combined pulse of water and DEZ constituted one full ALD cycle. The seamless integration of SIS and ALD cycles facilitated the controlled deposition of the UV protection layer on the models.
SIS-pulse (DEZ, 0.015 s)→exposure (1800 s)→purge (N₂, 900 s)→pulse (H₂O, 0.015 s)→exposure (1800 s)→purge (N₂, 900 s)
ALD-pulse (H₂O, 0.015 s)→purge (N₂, 10 s)→pulse (DEZ, 0.015 s)→purge (N₂, 10 s)

Reference is now made to FIG. 5 which shows graphs of typical pressure profiles for ALD and SIS processes according to some embodiments of the invention. The pressure profiles during the Atomic Layer Deposition (ALD) and Sequential Infiltration Synthesis (SIS) processes are crucial indicators of the reaction dynamics within the reactor. For the SIS process, the pressure range within the reactor during exposure to Diethylzinc (DEZ) pulses is observed to be between 2.5 and 4 Torr. Subsequently, during water exposure, the pressure values elevate to a range of 7-9 Torr. In contrast, the ALD process exhibits distinct pressure characteristics. Specifically, the pressure range within the reactor during DEZ exposure pulses is notably lower, ranging from 0.65 to 0.7 Torr. During water exposure in the ALD process, the pressure values vary within the range of 0.8-1.5 Torr. Moreover, during purge times, a consistent pressure level of approximately 0.6 Torr is maintained. These pressure data sets provide insights into the distinct atmospheric conditions and precursor behaviors during the ALD and SIS processes, contributing to a comprehensive understanding of the deposition mechanisms.

### Results

The UV resistance of the films was assessed a series of experiments, exposing the models to UV radiation at a wavelength of 253.7 nm with an intensity of 28˜32 mW/cm². The exposure periods included 15 minutes and 30 minutes. Measurements of the films' thickness were taken both before and after UV exposure, and the FTIR spectrum of the films was analyzed.

Reference is now made to FIG. 6 which shows FTIR spectrum of PLA after 10 SIS cycles+500 ALD cycles at varying time intervals of UV radiation exposure according to some embodiments of the invention. The illustrate spectrums includes, before UV exposure, after 15 minutes of exposure, and finally, after 30 minutes of exposure. These results align with the measurements of thickness and ZnO growth rate in the ALD process.

Tables 1 and 2 present a summary of the measurements capturing the film thickness before and after exposure to UV radiation across all conducted combinations of SIS & ALD. FIGS. 3 and 4 present a summary of the UV exposure experiment results, illustrating the percentage of remaining thickness of the PLA film after UV exposure.

TABLE 1
Thickness measurement results of 15 min UV exposure experiment

| | | Exposure | | % of |
|---|---|---|---|---|
| | Thickness | time | Thickness after | remaining |
| Recipe | (nm) | (min) | UV (nm) | thickness |
| pristine | 128.33 | 15 | 47.59 | 37.08 |
| 1 SIS cycle | 109.00 | | 74.72 | 68.55 |
| 5 SIS cycles | 88.20 | | 61.82 | 69.21 |
| 10 SIS cycles | 142.64 | | 82.34 | 57.73 |
| 200 ALD cycles | 96.31 | | 51.56 | 53.54 |
| 250 ALD cycles | 115.71 | | 77.38 | 66.87 |
| 500 ALD cycles | 90.12 | | 49.15 | 54.54 |
| 1 SIS cycle + | 129.35 | | 76.36 | 59.03 |
| 250 ALD cycles | | | | |
| 3 SIS cycles + | 107.62 | | 105.19 | 97.74 |
| 250 ALD cycles | | | | |
| 5 SIS cycles + | 123.95 | | 122.17 | 98.56 |
| 250 ALD cycles | | | | |
| 10 SIS cycles + | 107.23 | | 107.04 | 99.82 |
| 500 ALD cycles | | | | |

TABLE 2
Thickness measurement results of 30 min UV exposure experiment

| | | Exposure | Thickness | % of |
|---|---|---|---|---|
| | Thickness | time | after | remaining |
| Recipe | (nm) | (min) | UV (nm) | thickness |
| pristine | 128.33 | 30 | 2.91 | 37.08 |
| 1 SIS cycle | 109.00 | | 12.65 | 11.61 |
| 5 SIS cycles | 88.20 | | 10.35 | 11.73 |
| 10 SIS cycles | 142.64 | | 14.35 | 10.06 |
| 200 ALD cycles | 96.31 | | 1.98 | 2.06 |
| 250 ALD cycles | 115.71 | | 5.55 | 4.80 |
| 500 ALD cycles | 90.12 | | 4.39 | 4.87 |
| 1 SIS cycle + | 129.35 | | 8.29 | 6.41 |
| 250 ALD cycles | | | | |
| 3 SIS cycles + | 107.62 | | 104.05 | 96.68 |
| 250 ALD cycles | | | | |
| 5 SIS cycles + | 123.95 | | 121.15 | 97.74 |
| 250 ALD cycles | | | | |
| 10 SIS cycle + | 107.23 | | 105.16 | 98.07 |
| 500 ALD cycles | | | | |

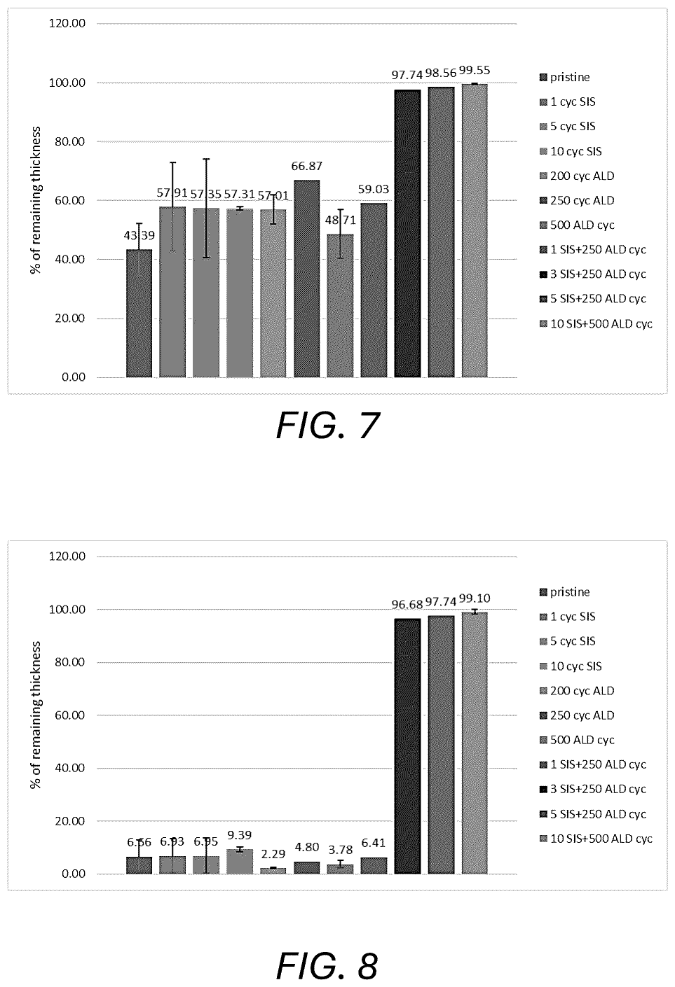

Reference is now made to FIG. 7 which shows the percentage of the remaining thickness of PLA thin film after 15 min under UV 28˜32 mW/cm²@253.7 nm; and to FIG. 8 the percentage of the remaining thickness of PLA thin film after 30 min under UV 28˜32 mW/cm²@253.7 nm. Both graphs shows the advantage of preforming at least 3 cycles of SIS in addition to at least 250 ADL cycles.

These findings distinctly reveal that individual SIS and ALD processes do not exhibit a noteworthy enhancement in the UV resistance of PLA. Conversely, a synergistic approach, where the SIS process precedes the ALD process, demonstrates a substantial improvement in PLA's resistance to UV radiation. This discovery can be correlated with the growth rate per cycle observed in the conducted ALD processes. ALD processes conducted subsequent to the SIS process exhibit a growth rate one order of magnitude higher compared to ALD processes performed on pristine PLA. As can be seen in Table 3.

TABLE 3
ALD Average mass gain per cycle (ug/cm2/cycle)

| | | Temp | Average mass gain |
|---|---|---|---|
| Recipe | substrate | C. ° | per cycle (ug/cm2) |
| 250 ALD cycles | PLA thin film | 80 | 0.00484 |
| 500 ALD cycles | PLA thin film | | 0.00688 |
| 250 ALD cycles | QCM quartz | | 0.0748 |
| 1 SIS cycle + | PLA thin film | | 0.00894 |
| 250 ALD cycles | after 1 SIS cycles | | |
| 3 SIS cycles + | PLA thin film | | 0.0612 |
| 250 ALD cycles | after 3 SIS cycles | | |
| 5 SIS cycles + | PLA thin film | | 0.08046 |
| 250 ALD cycles | after 5 SIS cycles | | |
| 10 SIS cycle + | PLA thin film | | 0.07965 |
| 500 ALD cycles | after 10 SIS cycles | | |

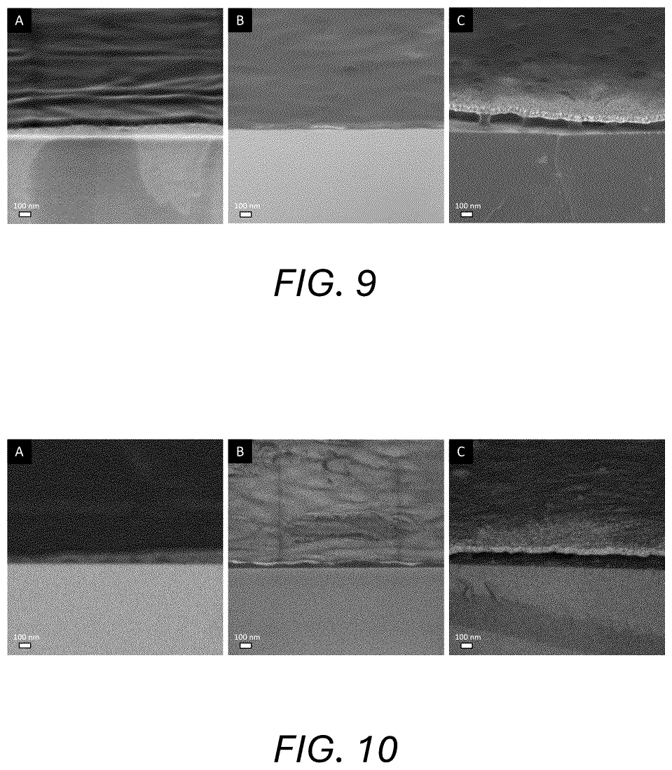

Reference is now made to FIG. 9 which includes SEM images of in lens cross section images of PLA thin film A) after 500 cycles of ALD B) after 10 cycles of SIS and C) after 10 SIS cycles followed by 500 ALD cycles according to some embodiments of the invention; and to FIG. 10 which includes SEM images of ESB cross section images of PLA thin film A) after 500 cycles of ALD B) after 10 cycles of SIS and C) after 10 SIS cycles followed by 500 ALD cycles.

FIGS. 9 and 10 show SEM cross-sectional images depict three thin films of poly(lactic acid) (PLA) subjected to atomic layer deposition (ALD) and sequential infiltration synthesis (SIS) processes. Analysis of the images reveals discernible distinctions among the various processes. Notably, after 500 cycles of ZnO ALD (FIGS. 9A and 9D), there is little presence of ZnO, as indicted by the minimal bright signal from the ESB detector that is associated with ZnO. Films with 10 cycles of ZnO SIS, on the other hand (FIGS. 9B and 9E), show higher presence of ZnO throughout the film. This difference is in good correlation with our microgravimetric measurements.

In films where the combined process of 10 SIS cycles followed by 500 ALD cycles was performed (FIGS. 9C and 9F), a significant difference was observed. These films not only have high ZnO content, as evident from the bright BSE signal, they also have formed a gap from the silicon substrate upon cross-section. The gap was attributed to the rigid, high toughness nature of the hybrid PLA-ZnO layer with high ZnO content which upon cross-section at cryogenic temperature partly detach from the substrate. In addition, the film's surface morphology becomes more granular, indicating growth of nanoscale ZnO. These results are in-line with our microgravimetric measurements, where the prelude of 10 SIS cycles appears to saturate substrate nucleation sites, resulting in a tenfold increase in the ALD growth rate. The robust resistance of film with the combined process to UV exposure is attributed to the substantial presence of the ZnO on top and within the film.

The disclosed UV radiation resistance enhancement technique, was primarily tested on polylactic acid (PLA) as a model system, therefore, the inventors are in view that similar techniques are suitable for other elastomers, either biodegradable or not.

The discloses method and article may present a breakthrough in addressing the UV sensitivity of widely used fossil fuel-derived plastics. Unlike current methods, the invention combines Sequential Infiltration Synthesis (SIS) and Atomic Layer Deposition (ALD) techniques, revealing a tenfold growth rate increase in zinc oxide (ZnO) when ALD follows SIS on the polymer film. This synergistic combination, previously unexplored for degradable polymers, allows for superior hybridization control and customization of UV resistance. The technology not only provides manufacturers with precise control over the coating process and uniformity on polymers but also ensures scalability for roll-to-roll manufacturing.

### Fabrication of Articles Comprising Other Polymeric Substrates

The effectiveness of the coating produced via the combined process was further demonstrated on additional polymers, including Polycarbonate (PC), Poly(methyl methacrylate) (PMMA), and Polyethylene terephthalate (PET). These polymers were processed at the following working temperatures: PC at 120° C., PET at 100° C., and PMMA at 95° C.

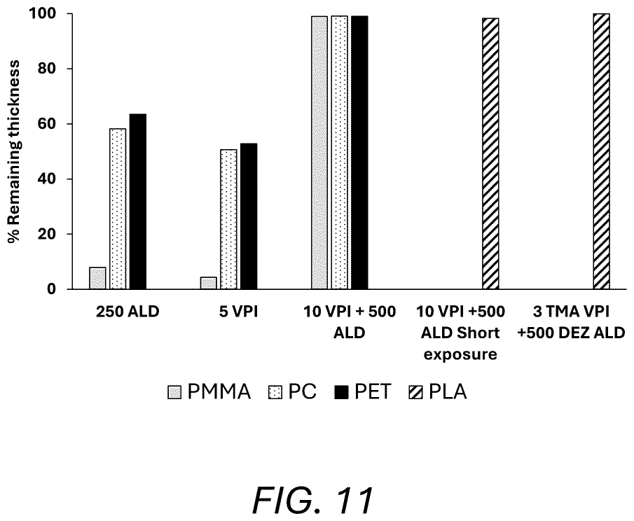

It was demonstrated that similar improvements in UV resistance for PLA can be achieved using significantly reduced exposure times in the VPI/SIS process. By decreasing the exposure duration from 30 minutes to 5 minutes and the purge time from 15 minutes to 2.5 minutes (resulting in a total cycle time of 15 minutes instead of 90 minutes), the overall process duration was reduced from approximately 18 hours to 5 hours. Remarkably, models processed under these shortened conditions exhibited comparable UV radiation resistance to those subjected to the longer process. Furthermore, TMA (trimethylaluminum) was utilized in place of DEZ (diethylzinc) during the SIS/VPI process to promote polymer nucleation prior to the ALD step. Samples treated with TMA exhibited UV resistance comparable to those processed with the standard combined method, demonstrating the versatility of the approach in achieving enhanced UV protection. The UV exposure results for these models are shown in FIG. 11.

FIG. 11 shows the percentage of the remaining thickness of PMMA, PC, PET and PLA film under UV 28˜32 mW/cm²@253.7 nm, thin films thickness ˜100 nm, according to some embodiments of the invention. For all three polymers, the coating significantly improved UV radiation resistance under 30 min of UV exposure.

### General

As used herein the term “about” refers to □10%.

The terms “comprises”, “comprising”, “includes”, “including”, “having” and their conjugates mean “including but not limited to”.

The term “consisting of means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

As used herein, the singular form “a”, “an” and “the” include plural references unless the context clearly dictates otherwise. For example, the term “a compound” or “at least one compound” may include a plurality of compounds, including mixtures thereof.

As used herein, the term “substantially” refers to at least 80%, at least 85%, at least 90%, at least 92%, at least 95%, at least 96%, at least 97%, at least 98%, at least 99%, including any range or value therebetween.

As used herein, the term “enhance” including any grammatical forms thereof, refers to least 10%, at least 20%, at least 30%, at least 40%, at least 50%, at least 60%, at least 70%, at least 100%, between 100 and 200%, between 200 and 300%, between 300 and 500%, between 500 and 1000%, between 1000 and 10000% including any range between, compared to a control.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

As used herein the term “method” refers to manners, means, techniques and procedures for accomplishing a given task including, but not limited to, those manners, means, techniques and procedures either known to, or readily developed from known manners, means, techniques and procedures by practitioners of the chemical, pharmacological, biological, biochemical and medical arts.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

Unless explicitly stated, the method embodiments described herein are not constrained to a particular order or sequence. Furthermore, all formulas described herein are intended as examples only and other or different formulas may be used. Additionally, some of the described method embodiments or elements thereof may occur or be performed at the same point in time.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

Various embodiments have been presented. Each of these embodiments may of course include features from other embodiments presented, and embodiments not specifically described may include various features described herein.

1. An article comprising:
a polymeric substrate;
metal oxide particles embedded in the polymeric substrate; and
a metal oxide layer coating the polymeric substrate,
wherein the polymeric substrate is a non-fibrous polymeric substrate.

2. The article of claim 1, wherein the metal oxide layer is at least one of, a continuous layer and a nonstructured layer.

3. The article of claim 2, wherein the nonstructured layer comprises high density needle-shaped nanostructures.

4. The article of claim 1, wherein the metal oxide particles are embedded in the polymeric substrate at a depth of at least 10 nm.

5. The article of claim 1, wherein the metal oxide layer is characterized by a thickness of between 10 and 500 nm.

6. The article of claim 5, wherein the thickness standard deviation is at most 3 nm.

7. The article of claim 1, wherein the polymeric substrate consists of a thermoplastic polymer.

8. The article of claim 1, wherein the polymeric substrate is devoid of any UV-related additives.

9. The article of claim 8, wherein the UV-related additives are selected from, UV absorbers, UV reflectors, UV blockers, and UV scatters.

10. The article of claim 1, wherein the polymeric substrate is a polymeric sheet.

11. The article of claim 10, wherein the polymeric sheet is characterized by a thickness between 0.1 μm and 1 mm.

12. The article of claim 1, wherein the metal oxide is characterized by at least one of, a UV-absorbing property and a UV-protective property.

13. The article of claim 1, wherein the metal oxide comprises ZnO, TiO2 or both.

14. A method of making an article according claim 1, the method comprising:
passivating a polymeric substrate with a precursor of a metal oxide, to obtain a passivated substrate comprising the metal oxide particles embedded in the polymeric substrate; and
depositing a metal oxide layer on the passivated polymeric substrate, wherein depositing is performed by atomic layer deposition (ALD); wherein passivating step comprises at least 3 repetitive cycles of sequential infiltration synthesis (SIS).

15. The method of claim 14, wherein the SIS comprises exposing the polymeric substrate with the precursor thereby depositing the precursor into the polymeric substrate; and oxidizing the precursor thereby obtaining the metal oxide.

16. The method of claim 14, wherein the exposing is performed at a pressure sufficient for the precursor to penetrate into the polymeric substrate.

17. The method of claim 15, wherein the pressure is at least about 2 Torr.

18. The method of claim 14, wherein the passivating step comprises between 3 and 50 repetitive cycles of SIS; and wherein the exposing is performed for a time period of at least 100 s.

19. The method of claim 14, wherein the ALD comprises exposing the passivated polymeric substrate with the precursor and oxidizing the precursor thereby obtaining the metal oxide.

20. The method of claim 19, wherein is performed at a pressure between 0.3 and 1 Torr.
